(19) United States
(12) Patent Application Publication
(10) Pub. No.: US 2013/0003330 A1
(43) Pub. Date: Jan. 3, 2013

(54) CONNECTION UNIT FOR ELECTRONIC DEVICES

(75) Inventor: SHIH-YI CHEN, Tu-Cheng (TW)

(73) Assignee: HON HAI PRECISION INDUSTRY CO., LTD., Tu-Cheng (TW)

(21) Appl. No.: 13/192,475

(22) Filed: Jul. 28, 2011

(30) Foreign Application Priority Data
Jun. 30, 2011 (TW) 100122985

(51) Int. Cl. H05K 7/02

(52) U.S. Cl. 361/760

(57) ABSTRACT

A connection unit for connecting additional electronic components to an electronic device includes a base board and at least one connection module. The base board is electrically connected to the electronic device. The at least one connection module is detachably assembled on and electrically connected to the base board. The additional electronic components are detachably assembled on the connection module and may be electrically connected to each other and (through the connection module and the base board) to the electronic device.

### BACKGROUND

1. Technical Field

The present disclosure relates to electronic devices, and particularly to a connection unit for electronic devices.

2. Description of Related Art

Circuit boards of electronic devices often need to have additional electronic components added in order to change functions of the electronic devices. Because most electrical connection lines of the circuit boards are formed on the circuit boards, it is difficult to directly connect the additional electronic components onto the circuit boards, and these additional electronic components may need to be connected to the circuit boards by solder. However, soldering is difficult and time consuming, and may cause damage to the circuit boards.

Therefore, there is room for improvement within the art.

### BRIEF DESCRIPTION OF THE DRAWINGS

Many aspects of the present disclosure can be better understood with reference to the following drawings. The components in the various drawings are not necessarily drawn to scale, the emphasis instead being placed upon clearly illustrating the principles of the present disclosure. Moreover, in the drawings, like reference numerals designate corresponding parts throughout the figures.

FIG. 1 is a schematic view of a connection unit, according to an exemplary embodiment, which is installed in an electronic device.

FIG. 2 is a cross-sectional view of one exemplary embodiment of the connection unit shown in FIG. 1.

FIG. 3 is an enlarged view of a base board and a connection module of the connection unit shown in FIG. 1, shown from another angle.

### DETAILED DESCRIPTION

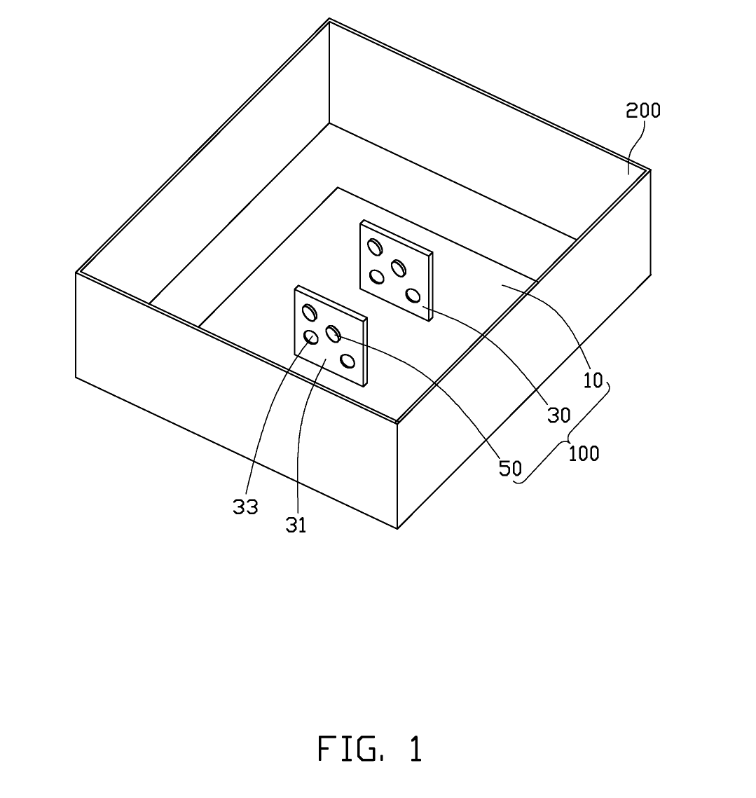

FIG. 1 is a schematic view of a connection unit 100, according to an exemplary embodiment. The connection unit 100 can be installed in an electronic device 200, such as in a mobile phone or a digital camera. Additional electronic components 50 for the electronic device 200, such as resistors, capacitors, transistors, and others, can be connected to the electronic device 200 through the connection unit 100 to add or change functions of the electronic device 200.

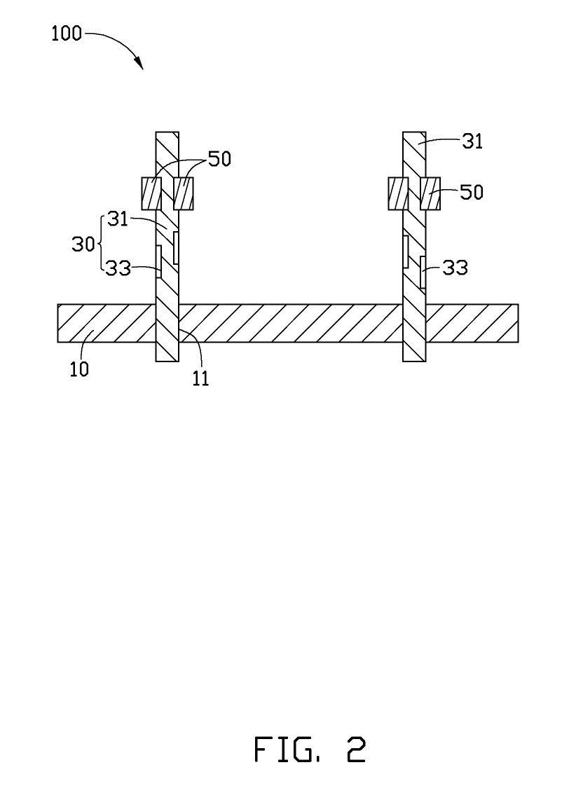

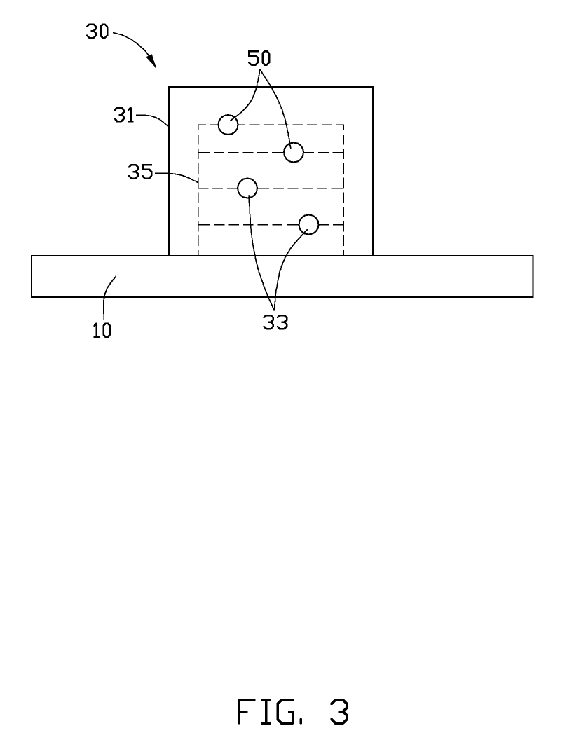

Also referring to FIG. 2 and FIG. 3, the connection unit 100 includes a base board 10 and at least one connection module 30 (the present disclosure shows two, but it should be understood that more than two connection modules 30 can be used in substantially the same manner). The base board 10 can be a part of a typical circuit board of the electronic device 200, or an independent circuit board that is electrically connected to the electronic device 200. At least one assembling slot 11 corresponding to the connection module(s) 30 is defined in the base board 10.

Each of the connection module(s) 30 includes a connection board 31. The connection board 31 can also be a circuit board, and can be inserted into the assembling slot 11 corresponding to the connection module 30 to be assembled on the base board 10. In assembly, the connection boards 31 are positioned so as to be perpendicular to the base board 10, to decrease the external length and width of the connection unit 100. Electronic connectors (not shown) of the connection boards 31 correspond to electronic connectors (not shown) of the base board 10. When the connection boards 31 are assembled on the base board 10 (i.e., received in their corresponding assembling slots 11), the electronic connectors of the connection boards 31 make contact with the electronic connectors of the base board 10, such that the connection boards 31 are electrically connected to the base board 10, and so electrically connected to the electronic device 200.

A plurality of connection members 33 which correspond to the additional electronic components 50 are formed in the connection board 31 of each of the connection module(s) 30. The connection members 33 are recessed portions formed on both sides of the connection board 31, and each of the connection members 33 includes electronic connectors (not shown) formed therein. Each of the additional electronic components 50 can be inserted into one of the corresponding connection members 33. When the additional electronic components 50 are assembled on the connection board 31 (i.e., received in their corresponding connection slots 33), they all make semi-permanent electrical contact with the electronic connectors of the connection members 33.

Also referring to FIG. 3, each of the connection modules 30 can further include electrical pathways or tracks (i.e., electrical connection lines 35). The electrical connection lines 35 are formed inside the connection boards 31. In each of the connection modules 30, the electrical connection lines 35 electrically connect the electric connectors of selected connection members 33 to each other according to predetermined patterns. Thus, the additional electronic components 50 respectively received in these selected connection members 33 are electrically connected to each other according to the predetermined patterns on and/or through the connection board 31, and cooperatively form circuits with predetermined functions. Additionally, the additional electronic components 50 respectively received in the selected connection members 33 can also be electrically connected to each other by external wires (not shown) soldered to these additional electrical electronic components 50 or directly to the connection module 30 in accordance with the predetermined patterns, thereby forming circuits with predetermined functions.

Furthermore, additional electronic components 50 respectively received in some or all of the connection members 33 of different connection modules 30 can be electrically connected to each other by external wires (not shown) soldered to each other and to these additional electrical electronic components 50 or to the connection modules 30, in accordance with predetermined patterns, thereby forming circuits with predetermined functions.

In use, the additional electronic components 50 are inserted into some or all of the connection members 33 for assembly on and electrical connection to the connection board(s) 31, and are further electrically connected to each other according to predetermined patterns to form circuit(s) with predetermined functions, in accordance with the aforementioned methods. The connection board(s) 31 is/are inserted into corresponding assembling slot(s) 11 to be assembled on and electrically connected to the connection board 10. In this way, the circuit(s) formed by or developed by these additional electronic components 50 is/are electrically connected to the electronic device 200 through the connection unit 100 to add to or change or extend the functions of the electronic device 200.

In the aforementioned use process, as detailed above, the additional electronic components 50 which are received in some or all of the connection members 33 of the same connection module 30 can be electrically connected to each other by the electrical connection lines 35 of the connection module 30, or external wires soldered to these additional electronic components 50 or to the connection module 30. The additional electronic components 50 respectively received in some or all of the connection members 33 of different connection modules 30 can be electrically connected to each other by external wires soldered to these additional electronic components 50 or to the connection module 30. In each of above connection methods, no wire needs to be soldered to any part of a circuit board of the electronic device 200 (e.g., the base board 10), and thus the circuit board of the electronic device 200 is not required to endure or undergo any soldering process.

Furthermore, the circuit(s) formed by the additional electronic components 50 can be removed from the electronic device 200 by pulling out the connection board(s) 31 from the assembling slots 11. The functionality and relevant parameters of the circuit(s) formed by the additional electronic components 50 can be changed by separating one or more of the additional electronic components 50 assembled on the connection board(s) 31 from their corresponding connection members 33, substituting one or more of the additional electronic components 50 assembled on the connection board(s) 31, or adding and assembling more additional electronic components 50 into any unused connection members 33 of the connection board(s) 31. Accordingly, compared with typical current methods, the present disclosure can be assembled, used, adjusted, and disassembled more easily.

It is to be further understood that even though numerous characteristics and advantages of the present embodiments have been set forth in the foregoing description, together with details of structures and functions of various embodiments, the disclosure is illustrative only, and changes may be made in detail, especially in matters of shape, size, and arrangement of parts within the principles of the present invention to the full extent indicated by the broad general meaning of the terms in which the appended claims are expressed.

What is claimed is:

1. A connection unit for connecting an electronic device with additional electronic components, the connection unit comprising:
a base board electrically connected to the electronic device; and
at least one connection module detachably assembled on and electrically connected to the base board; wherein the additional electronic components are detachably assembled on the connection module and electrically connected to the electronic device through the connection module and the base board.

2. The connection unit as claimed in claim 1, wherein the base board is a part of a circuit board of the electronic device or an independent circuit board electrically connected to the circuit board of the electronic device.

3. The connection unit as claimed in claim 1, wherein the connection module includes a connection board and the base board defines at least one assembling slot corresponding to the connection board; the connection board detachably received in the assembling slot to be assembled on and electrically connected to the base board.

4. The connection unit as claimed in claim 3, wherein the connection board is positioned to be perpendicular to the base board when the connection board is assembled on the base board.

5. The connection unit as claimed in claim 3, wherein the connection module further includes a plurality of connection members formed in the connection board; the connection member being recessed portions corresponding to the additional electronic components, and the additional electronic components detachably received in the connection members to be assembled on the connection board and electrically connected to the electronic device through connection board and the base board.

6. The connection unit as claimed in claim 5, wherein the connection members are formed in both two opposite sides of the connection board.

7. The connection unit as claimed in claim 5, wherein the connection module further includes electronic connection lines formed inside the connection board; the electrical connection lines electrically connecting selected ones of the connection members to each other according to predetermined patterns, such that the additional electronic components respectively received in these selected connection members are electrically connected to each other according to the predetermined patterns through the connection board, and thereby form circuits detachably electrically connected to the electronic device through the base board to add or change functions of the electronic device.

8. The connection unit as claimed in claim 5, wherein the additional electronic components respectively received in selected connection members of the connection module are electrically connected to each other according to predetermined patterns through external wires, and thereby form circuit detachably electrically connected to the electronic device through the base board to add or change functions of the electronic device.

9. The connection unit as claimed in claim 5, further comprising a plurality of the connection modules; wherein the additional electronic components respectively received in selected connection members of different connection modules are electrically connected to each other according to predetermined patterns through external wires, and thereby form circuits detachably electrically connected to the electronic device through the base board to add or change functions of the electronic device.
